(19) United States
(12) Patent Application Publication
(10) Pub. No.: US 2025/0037993 A1
(43) Pub. Date: Jan. 30, 2025

(54) METHOD FOR FORMING SILICON NITRIDE FILM SELECTIVELY ON SIDEWALLS OF TRENCHES

(71) Applicant: ASM IP Holding B.V., Almere (NL)

(72) Inventors: Tomomi Ban, Tokyo (JP); Annisa Noorhidayati, Tokyo (JP); Ling Chi Hwang, Tokyo (JP)

(21) Appl. No.: 18/777,790

(22) Filed: Jul. 19, 2024

Related U.S. Application Data
(60) Provisional application No. 63/528,455, filed on Jul. 24, 2023.

(51) Int. Cl. H01L 21/02

(52) U.S. Cl. CPC H01L 21/02274; H01L 21/0217; H01L 21/02211

(57) ABSTRACT

A method of forming dielectric material layer on a surface of a substrate is provided. The method may comprise: providing a substrate within a reaction chamber; flowing a precursor on the substrate within the reaction chamber; flowing a reactant on to the substrate; and generating a plasma by a dual radio frequency (RF) plasma source including a high frequency (HF) component and a low frequency (LF) component. By generating the plasma, the precursor reacts with the reactant to form a layer and a pressure in the reaction chamber during at least the step of providing the plasma is between 2,000 and 4,000 Pa.

### CROSS-REFERENCE TO RELATED APPLICATIONS

This application claims priority to U.S. Provisional Patent Application Ser. No. 63/528,455 filed Jul. 24, 2023 titled METHOD FOR FORMING SILICON NITRIDE FILM SELECTIVELY ON SIDEWALLS OF TRENCHES, the disclosure of which is hereby incorporated by reference in its entirety.

### FIELD OF INVENTION

The present disclosure generally relates to methods for forming silicon nitride film. More particularly, examples of the disclosure relate to methods for forming silicon nitride film selectively on sidewalls of trenches using plasma.

### BACKGROUND OF THE DISCLOSURE

In manufacturing processes of large-scale integrated circuits (LSIs), there are several processes for forming sidewalls in trenches. The sidewalls are used as spacers or used for blocking etching of a structure from side surfaces of trenches. Conventionally, the sidewalls were formed by forming a conformal film on surfaces of trenches, and then removing portions thereof formed on an upper surface in which the trenches were formed and portions formed on bottom surfaces of the trenches by asymmetrical etching. However, when such a formation method is used, over-etching is required in order to remove footing of sidewalls in which the thickness of the sidewalls increases near and at the bottom, forming a slope. Over-etching causes etching of an underlying layer and causes damage to a layer structure.

One approach for forming sidewalls in trenches is to use high RF power under low pressure. An exemplary method is disclosed in U.S. Pat. No. 9,754,779, which is hereby incorporated by reference. There is a need to use high pressure when sidewalls are formed in trenches.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a method of forming a layer in a trench formed in an upper surface of a substrate is provided. The method may comprise providing a substrate within a reaction chamber; flowing a precursor on the substrate within the reaction chamber; flowing a reactant on to the substrate; and generating a plasma by a dual radio frequency (RF) plasma source including a high frequency (HF) component and a low frequency (LF) component; wherein the precursor reacts with the reactant to form a layer; wherein a pressure in the reaction chamber during at least the step of providing the plasma is between 2,000 and 4,000 Pa.

In various embodiments, the high frequency (HF) may have a frequency in a range between about 13 MHz and about 27 MHz and the low frequency (LF) power may have a frequency in a range between about 100 KHz and about 500 KHz.

In various embodiments, the high frequency RF power may be between about 400 watts and about 800 watts and the low frequency RF power may be between about 400 watts and about 800 watts.

In various embodiments, the reactant may be provided continuously.

In various embodiments, a duration of flowing the precursor may be between about 0.3 and about 2.0 seconds.

In various embodiments, a duration of generating the plasma may be between about 0.5 and about 30 seconds.

In various embodiments, a temperature within the reaction chamber may be between about 350° C. and about 450° C.

In various embodiments, the layer may comprise a dielectric layer containing a Si—N bond.

In various embodiments, a thickness of the dielectric layer may be between 4 nm and 15.

In various embodiments, the precursor may comprise at least one of: a silane, a silylamine, an aminosilane, or a halogenated silicon compound.

In various embodiments, the precursor may comprise at least one of: silane (SiH4), disilane (Si2H6), trisilane (Si3H8), tetrasilane (Si4H10), N(Si2H5)3, trisilylamine N(SiH3)3, N(SiMe3)(SiHMeNMe2)2, 2,2-disilyltrisilane (Si(SiH3)4), trisdimethylaminosilane (SiH(NMe2)3), bis(diethylamino)silane (SiH2(NEt2)2)(BEDAS), bis(tert-butylamino)silane (SiH2(NHtBu)2)(BTBAS), di-isopropylamido)silane (SiH3(NiPr2))(DIPAS), where Me represents a methyl group, Et represents an ethyl group, tBu represents a tert-butyl group, and iPr represents an isopropyl group, trichloro disilane (Si2Cl3H3), pentachloro disilane (Si2Cl5H), hexachloro disilane (Si2Cl6), octachlorotrisilane (Si3Cl8), dichloro silane (SiCl2H2), dimethyldichlorosilane (SiCl2Me2), tetrachloro silane (SiCl4), tetraiodo silane (SiI4), triiodo silane (SiI3H), or diiodo silane (SiI2H2).

In various embodiments, the reactant may comprise a nitrogen precursor.

In various embodiments, the nitrogen precursor may comprise at least one of: N2, NH3, a mixture of N2 and H2, or combinations thereof.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a timing sequence in accordance with exemplary embodiments of the disclosure.

FIG. 3a illustrates a graph showing the relationship between RF power and wet etching rate of a film formed on a top surface and that of a film formed on sidewalls of a trench in a prior art reference.

FIG. 3b illustrates a graph showing the relationship between RF power and wet etching rate of a film formed on a top surface and that of a film formed on sidewalls of a trench in accordance with exemplary embodiments of the disclosure.

FIG. 4 illustrates scanning transmission electron microscopy images of structures in accordance with exemplary embodiments of the disclosure.

FIG. 5 illustrates a plasma reactor system 500 in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas, carrier gas, and dilution gas refer to a gas that does not take part in a chemical reaction to an appreciable extent and/or a gas that can excite a precursor when plasma power is applied.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

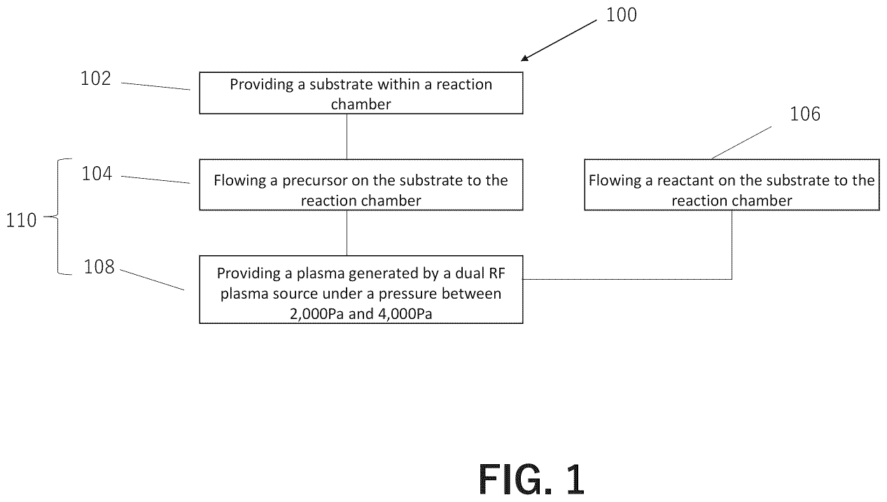

FIG. 1 illustrates a method 100 of forming film selectively on sidewalls of trenches in accordance with exemplary embodiments of the disclosure. Method 100 include: providing a substrate within a reaction chamber (102); flowing a precursor on the substrate within the reaction chamber (104); flowing a reactant on to the substrate (106); and generating a plasma by a dual radio frequency (RF) plasma source including a high frequency (HF) component and a low frequency (LF) component (108). By providing the plasma, the precursor reacts with the reactant to form a layer. Further, a pressure in the reaction chamber during at least the step of providing the plasma is between 2,000 and 4,000 Pa.

As shown in FIG. 1, during the step 102, a substrate is provided into a reaction chamber of a gas-phase reactor. In accordance with examples of the disclosure, the reaction chamber can form part of an atomic layer deposition reactor, such as a plasma-enhanced atomic layer deposition (PEALD) reactor.

During the step 102, the substrate can be brought to a desired temperature and the reaction chamber can be brought to a desired pressure, such as a temperature and pressure suitable for subsequent steps. By way of examples, a temperature (e.g., of a substrate or a substrate support) within a reaction chamber can be between 350° C. and 450° C. In accordance with particular examples of the disclosure, the substrate includes one or more features, such as trenches.

During the flowing the precursor on the substrate to the reaction chamber step 104, the precursor for forming the film is introduced into the reaction chamber. Exemplary precursor may include at least one of: a silane, a silylamine, an aminosilane, or a halogenated silicon compound. Exemplary precursor may comprise at least one of: silane (SiH4), disilane (Si2H6), trisilane (Si3H8), tetrasilane (Si4H10), N(Si2H5)3, trisilylamine N(SiH3)3, N(SiMe3)(SiHMeNMe2)2, 2,2-disilyltrisilane (Si(SiH3)4), trisdimethylaminosilane (SiH(NMe2)3), bis(diethylamino)silane (SiH2(NEt2)2)(BEDAS), bis(tert-butylamino)silane (SiH2(NHtBu)2)(BTBAS), di-isopropylamido)silane (SiH3(NiPr2))(DIPAS), where Me represents a methyl group, Et represents an ethyl group, tBu represents a tert-butyl group, and iPr represents an isopropyl group, trichloro disilane (Si2Cl3H3), pentachloro disilane (Si2Cl5H), hexachloro disilane (Si2Cl6), octachlorotrisilane (Si3Cl8), dichloro silane (SiCl2H2), dimethyldichlorosilane (SiCl2Me2), tetrachloro silane (SiCl4), tetraiodo silane (SiI4), triiodo silane (SiI3H), or diiodo silane (SiI2H2).

During the step 106, the reactant can be provided to the reaction chamber. Exemplary reactants provided during step 106 may include a nitrogen precursor. Exemplary nitrogen precursor may comprise at least one of: N2, NH3, a mixture of N2 and H2, or combinations thereof.

During the providing plasma step 108, the plasma is generated using a direct plasma system by a dual radio frequency (RF) plasma source including a high frequency (HF) component and a low frequency (LF) component 108. By the providing the plasma, the precursor reacts with the reactant to form a layer. The high frequency (HF) may have a frequency in a range between about 13 MHz and about 27 MHz and the low frequency (LF) power may have a frequency in a range between about 100 KHz and about 500 KHz. The high frequency RF power may be between about 400 watts and about 800 watts and the low frequency RF power may be between about 400 watts and about 800 watts.

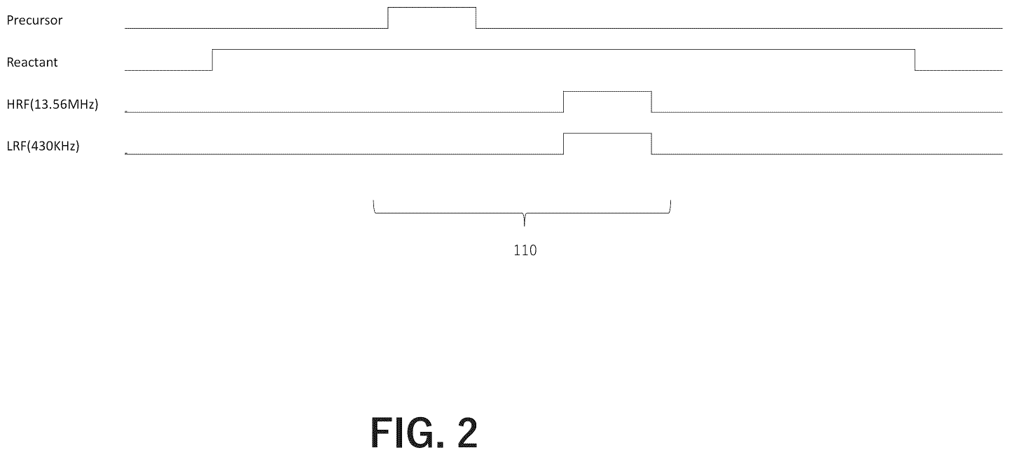

FIG. 2 illustrates a timing sequence in accordance with exemplary embodiments of the disclosure. The reactant may be provided continuously. A duration of flowing the precursor may be between about 0.3 and about 2.0 seconds. A duration of generating the plasma may be between about 0.5 and about 30 seconds. The step 110 can be repeated a number of times, for example 200-800 cycles, to form a layer. A thickness of the dielectric layer may be between 4 nm and 15.

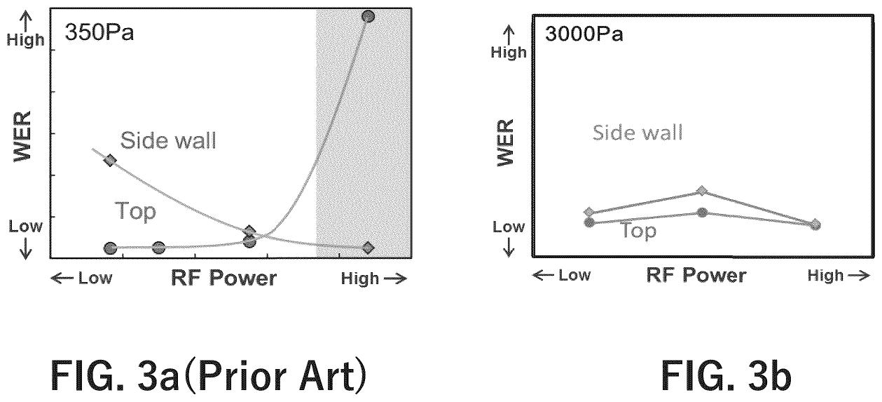

FIG. 3a illustrates a graph showing the relationship between HRF power and wet etching rate of a film formed on a top surface and that of a film formed on sidewalls of a trench in a prior art reference. The pressure is 350 Pa. The wet etch rate of the sidewall portion decreased as HRF power increased, whereas the wet etch rate of the top/bottom portions increased as the HRF power increased, wherein the line representing the former and the line representing the latter intersect at an HRF power of approximately 600 W. That is, the threshold HRF power was approximately 600 W, and it can be understood that when HRF power applied between the electrodes is higher than approximately 600 W, the top/bottom portions of the film can be removed selectively relative to the sidewall portion of the film, whereas when HRF power applied between the electrodes is lower than approximately 600 W, the sidewall portion of the film can be removed selectively relative to the top/bottom portions of the film.

FIG. 3b illustrates a graph showing the relationship between HRF power and wet etching rate of a film formed on a top surface and that of a film formed on sidewalls of a trench in accordance with exemplary embodiments of the disclosure. The wet etch rate of the sidewall portion and the top/bottom portions maintained as HRF power increased under a high pressure, which is 3000 Pa.

### Example

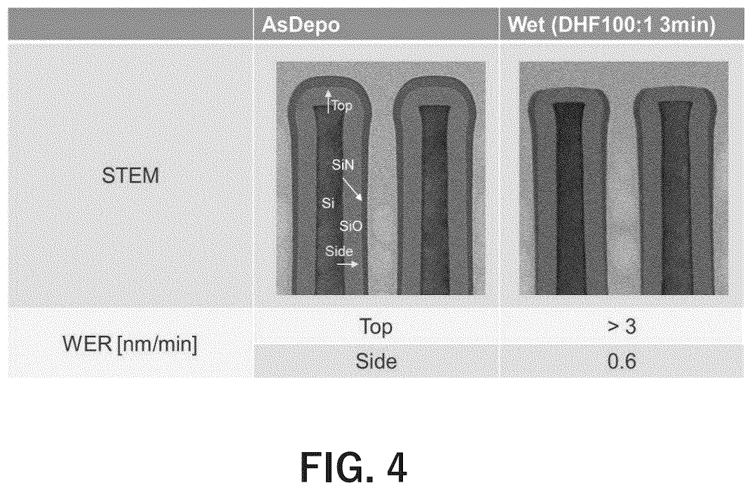

A SiN film was formed on a Si substrate (0300 mm) having trenches by PEALD, one cycle of which was conducted under the conditions shown in Table 1 below using the PEALD apparatus illustrated in FIG. 4. After taking out the substrate from the reaction chamber, the substrate was subjected to wet etching under the conditions shown in Table 1 below.

TABLE 1

| Conditions for Deposition | | |
|---|---|---|
| Substrate temperature | 350-450 | |
| RC pressure(torr) | 15-22.5 | |
| Precursor pulse (sec) | 0.3-2.0 | |
| Precursor purge (sec) | 1.0-6.0 | |
| Reactant | N2 | |
| Flow rate of reactant (continuous) | 19 | slm |
| Flow rate of carrier gas | 9 | slm |
| Flow rate of seal gas (continuous) | 3 | slm |
| HRF Power (w) | 400-800 | w |
| LRF Power (w) | 400-800 | w |

| | |
|---|---|
| RF power pulse (sec) | 0.5-30 |
| Number of cycles (thickness of film) | 200-800 times (4-15 nm) |
| Trench depth/width (nm) | 300/30 |
| Gap between electrodes(mm) | 12 |
| Conditions for Wet etching | |
| Etching solution | dHF 100:1 |
| Duration of etching (min) | 3 |
| Etching rate | Variable (see FIG. 4) |

(Numbers are approximate)

FIG. 4 illustrates scanning transmission electron microscopy images of structures in accordance with exemplary embodiments of the disclosure. By using dual frequency HRF/LRF (i.e. LRF is also added), reverse topological selectivity (RTS) can be accomplished even under the high pressure.

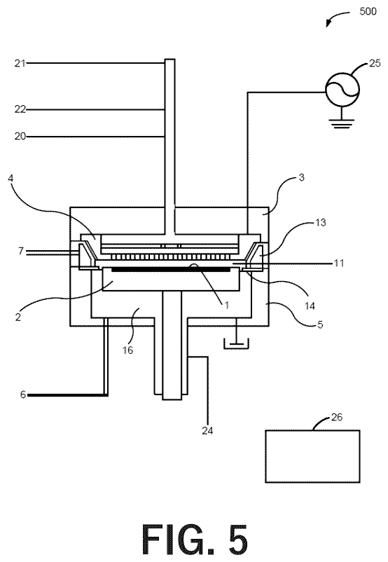

FIG. 5 illustrates a plasma reactor system 500 in accordance with exemplary embodiments of the disclosure. The plasma reactor system 500 can be used to perform one or more steps or sub steps as described herein and/or to form one or more structures or portions thereof as described herein.

The plasma reactor system 500 may include a pair of electrically conductive flat-plate electrodes 4, 2 in parallel and facing each other in an interior 11 (reaction zone) of a reaction chamber 3. A plasma can be excited within the reaction chamber 3 by applying HF power (e.g., 13.56 MHz or 27 MHz) and LF power (e.g. 450 k Hz) from a power source 25 to one electrode (e.g., electrode 4) and electrically grounding the other electrode (e.g., electrode 2). A temperature regulator may be provided in a lower stage 2 (the lower electrode), and a temperature of a substrate 1 placed thereon may be kept at a desired temperature. The electrode 4 may serve as a gas distribution device, such as a shower plate. Reactant gas, dilution gas, if any, precursor gas, and/or the like may be introduced into reaction chamber 3 using one or more of a gas line 20, a gas line 21, and a gas line 22, respectively, and through the shower plate 4. Although illustrated with three gas lines, the reactor system 500 may include any suitable number of gas lines.

In the reaction chamber 3, a circular duct 13 with an exhaust line 7 may be provided, through which gas in the interior 11 of the reaction chamber 3 may be exhausted. Additionally, a transfer chamber 5, disposed below the reaction chamber 3, may be provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone may be provided (a gate valve through which a wafer is transferred into or from the transfer chamber 5 is omitted from this figure). The transfer chamber may be also provided with an exhaust line 6. In some embodiments, the deposition and treatment steps may be performed in the same reaction space, so that two or more (e.g., all) of the steps can continuously be conducted without exposing the substrate to air or other oxygen-containing atmosphere.

In some embodiments, continuous flow of an inert or carrier gas to the reaction chamber 3 can be accomplished using a flow-pass system (FPS), wherein a carrier gas line may be provided with a detour line having a precursor reservoir (bottle), and the main line and the detour line may be switched, wherein when only a carrier gas may be intended to be fed to a reaction chamber, the detour line is closed, whereas when both the carrier gas and a precursor gas are intended to be fed to the reaction chamber, the main line may be closed and the carrier gas may flow through the detour line and flow out from the bottle together with the precursor gas. In this way, the carrier gas may continuously flow into the reaction chamber, and may carry the precursor gas in pulses by switching between the main line and the detour line, without substantially fluctuating pressure of the reaction chamber.

A skilled artisan will appreciate that the apparatus includes one or more controller(s) 26 programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan.

In some embodiments, a multiple chamber reactor (two or more sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a layer in a trench formed in an upper surface of a substrate, comprising:
providing a substrate within a reaction chamber;
flowing a precursor on the substrate within the reaction chamber;
flowing a reactant on the substrate within the reaction chamber; and
generating a plasma by a dual radio frequency (RF) plasma source including a high frequency (HF) component and a low frequency (LF) component;
wherein the precursor reacts with the reactant to form a layer;
wherein a pressure in the reaction chamber during at least the step of providing the plasma is between 2,000 and 4,000 Pa.

2. The method of claim 1, wherein the high frequency (HF) has a frequency in a range between about 13 MHz and about 27 MHz and the low frequency (LF) power has a frequency in a range between about 100 KHz and about 500 KHz.

3. The method of claim 1, wherein the high frequency RF power is between about 400 watts and about 800 watts and the low frequency RF power is between about 400 watts and about 800 watts.

4. The method of claim 1, wherein the reactant is provided continuously.

5. The method of claim 1, wherein a duration of flowing the precursor is between about 0.3 and about 2.0 seconds.

6. The method of claim 1, wherein a duration of generating the plasma is between about 0.5 and about 30 seconds.

7. The method of claim 1, wherein a temperature within the reaction chamber is between about 350° C. and about 450° C.

8. The method of claim 1, wherein the layer comprises a dielectric layer containing a Si—N bond.

9. The method of claim 8, wherein a thickness of the dielectric layer is between 4 nm and 15.

10. The method of claim 1, wherein the precursor comprises at least one of: a silane, a silylamine, an aminosilane, or a halogenated silicon compound.

11. The method of claim 10, wherein the precursor comprises at least one of: silane (SiH4), disilane (Si2H6), trisilane (Si3H8), tetrasilane (Si4H10), N(Si2H5)3, trisilylamine N(SiH3)3, N(SiMe3)(SiHMeNMe2)2, 2,2-disilyltrisilane (Si(SiH3)4), trisdimethylaminosilane (SiH(NMe2)3), bis(diethylamino)silane (SiH2(NEt2)2)(BEDAS), bis(tert-butylamino)silane (SiH2(NHtBu)2)(BTBAS), di-isopropylamido)silane (SiH3(NiPr2))(DIPAS), where Me represents a methyl group, Et represents an ethyl group, tBu represents a tert-butyl group, and iPr represents an isopropyl group, trichloro disilane (Si2Cl3H3), pentachloro disilane (Si2Cl5H), hexachloro disilane (Si2Cl6), octachlorotrisilane (Si3Cl8), dichloro silane (SiCl2H2), dimethyldichlorosilane (SiCl2Me2), tetrachloro silane (SiCl4), tetraiodo silane (SiI4), triiodo silane (SiI3H), or diiodo silane (SiI2H2).

12. The method of any claim 1, wherein the reactant comprises a nitrogen precursor.

13. The method of claim 12, wherein the nitrogen precursor comprises at least one of: N2, NH3, a mixture of N2 and H2, or combinations thereof.
